(19) United States
(12) Patent Application Publication
(10) Pub. No.: US 2015/0070815 A1
(43) Pub. Date: Mar. 12, 2015

(54) ELECTROSTATIC CHUCK MEMBER

(71) Applicants: Hironori Kugimoto, Tokyo (JP); Kazuto Ando, Tokyo (JP)

(72) Inventors: Hironori Kugimoto, Tokyo (JP); Kazuto Ando, Tokyo (JP)

(21) Appl. No.: 14/374,537

(22) PCT Filed: Aug. 3, 2012
(86) PCT No.: PCT/JP2012/069841

§ 371 Date: Jul. 25, 2014

(30) Foreign Application Priority Data
Jan. 30, 2012 (JP) 2012-016943

(51) Int. Cl. H01L 21/683

(52) U.S. Cl. CPC H01L 21/6833; Y10S 977/932; B82Y 15/00
USPC 361/234; 977/932

(57) ABSTRACT

There is provided an electrostatic chuck member made of a complex oxide sintered body obtained by substituting some of yttrium in yttrium aluminum oxide with a rare earth element (RE) excluding yttrium, in which a ratio [N_{RE}/(N_{Y}+N_{RE})] of the number of atoms of the rare earth element excluding yttrium (N_{RE}) to the sum (N_{Y}+N_{RE}) of the number of yttrium atoms (N_{Y}) and the number of the atoms of the rare earth element excluding yttrium (N_{RE}) is in a range of 0.01 to less than 0.5, and a volume resistance of the complex oxide sintered compact is in a range of 1×10¹⁰ Ω·cm to less than 1×10¹⁵ Ω·cm.

### TECHNICAL FIELD

The present invention relates to an electrostatic chuck member used in an electrostatic chuck apparatus.

### BACKGROUND ART

A Conventional a semiconductor line such as IC, LSI, and VLSI included steps in which halogen-based corrosive gas such as fluorine-based corrosive gas and chlorine-based corrosive gas and plasma thereof were used. Especially, in step such as dry etching step, plasma etching step, and cleaning step, fluorine-based gas such as CF₄, SF₆, HF, NF₃, and F₂ or chlorine-based gas such as Cl₂, SiCl₄, BCl₃, and HCl is used, and constituent members of a semiconductor manufacturing apparatus are required to have excellent corrosion resistance.

Here, a chuck apparatus is used to hold a wafer in a film-forming apparatus such as a CVD apparatus and a sputtering apparatus, an etching apparatus for carrying out a fine process, and the like, which are used in the semiconductor manufacturing line. A various types of chuck apparatuses have been known, and an electrostatic chuck-type chuck apparatus has been used in consideration of the correction of the wafer flatness, a heating uniformity, and the like.

In recent developments, materials in which a rare earth oxide (RE₂O₃) having no yttrium is added into an yttrium aluminum oxide crystal structure have been proposed to be used as a corrosion-resistant material for an electrostatic chuck, which is capable of exhibiting excellent corrosion resistance in the semiconductor manufacturing line (For example, refer to PTL 1 to 3).

### CITATION LIST

### Patent Literature

[PTL 1] Japanese Unexamined Patent Application Publication No. 2004-315308
[PTL 2] Japanese Unexamined Patent Application Publication No. 2001-151559
[PTL 3] Japanese Unexamined Patent Application Publication No. 10-236871

### SUMMARY OF INVENTION

### Technical Problem

An electrostatic chuck is a member for fixing a wafer in a semiconductor manufacturing apparatus, and is required to have a high dielectric-polarization (a high relative permittivity) to obtain a strong adsorption force from surface charges generated on the surface due to the application of a voltage. However, the above-described corrosion-resistant materials of the related art (PTL 1 to 3) have a low relative permittivity and a weak adsorption force. While there is a method for increasing the absorption force by decreasing the thickness of the electrostatic chuck material, there is a problem in that it was not possible to apply a sufficient voltage because of decrease of the voltage resistance or the corrosion-resistant material cracked during a process in a case that the corrosion-resistant material is used for an electrostatic chuck.

The invention has been made to solve the above-described problems, and an object of the invention is to provide an electrostatic chuck member which is available in halogen-based corrosive gas such as fluorine-based corrosive gas or chlorine-based corrosive gas and plasma thereof and has a sufficient adsorption force and a sufficient mechanical strength.

### Solution to Problem

As a result of intensive studies, the inventors found that, when at least a portion of a member which is exposed to corrosive gas or plasma thereof is made of a complex oxide sintered body obtained by substituting some of yttrium in yttrium aluminum oxide with a rare earth element (RE) excluding yttrium, in the sintered body, a ratio [N_{RE}/(N_{Y}+N_{RE})] of the number of atoms of the rare earth element excluding yttrium (N_{RE}) to the sum (N_{Y}+N_{RE}) of the number of yttrium atoms (N_{Y}) and the number of the atoms of the rare earth element excluding yttrium (N_{RE}) is in a range of 0.01 to less than 0.5, and the volume resistance of the sintered body is in a range of 1×10¹⁰ Ω·cm to less than 1×10¹⁵ Ω·cm, it is possible to obtain an electrostatic chuck member having a sufficient adsorption force and a sufficient mechanical strength in spite of a low relative permittivity, and completed the invention.

That is, the invention is as described below.

[1] An electrostatic chuck member made of a complex oxide sintered body obtained by substituting some of yttrium in yttrium aluminum oxide with a rare earth element (RE) excluding yttrium, in which a ratio [N_{RE}/(N_{Y}+N_{RE})] of the number of atoms of the rare earth element excluding yttrium (N_{RE}) to the sum (N_{Y}+N_{RE}) of the number of yttrium atoms (N_{Y}) and the number of the atoms of the rare earth element excluding yttrium (N_{RE}) is in a range of 0.01 to less than 0.5, and a volume resistance of the complex oxide sintered body is in a range of 1×10¹⁰ Ω·cm to less than 1×10¹⁵ Ω·cm.

[2] The electrostatic chuck member according to [1], in which an average particle diameter of the complex oxide sintered body is in a range of 0.5 μm to 30 μm.

[3] The electrostatic chuck member according to [1] or [2], in which a dielectric loss (tan δ) of the complex oxide sintered body is in a range of 0.01 to less than 1 at 40 Hz, is in a range of 0.001 to less than 0.1 at 1 kHz, and is 0.001 or less at 1 MHz.

[4] The electrostatic chuck member according to any one of [1] to [3], in which the rare earth element (RE) excluding yttrium is samarium and/or gadolinium.

[5] The electrostatic chuck member according to any one of [1] to [4], in which, in the complex oxide sintered body, a lattice constant of a garnet-type crystal phase being contained is in a range of more than 1.2005 nm to 1.2060 nm.

### Advantageous Effects of Invention

According to the invention, it is possible to provide an electrostatic chuck member which is available in halogen-based corrosive gas such as fluorine-based corrosive gas or chlorine-based corrosive gas and plasma thereof and has a sufficient adsorption force and a sufficient mechanical strength.

### BRIEF DESCRIPTION OF DRAWING

FIG. 1 is a view illustrating relationships between applied voltages and adsorption forces of sintered bodies of Examples 1 and 8 and Comparative Example 1.

### DESCRIPTION OF EMBODIMENTS

An electrostatic chuck member of the invention is made of a complex oxide sintered body obtained by substituting some of yttrium in yttrium aluminum oxide with a rare earth element (RE) excluding yttrium.

The following documents are known to describe that the conductive property is developed by introducing a second phase component into a ceramic matrix, and the adsorption force is improved.

“Effect of Additives on the Electrostatic Force of Alumina Electrostatic Chucks” (Toshiya WATANABE and Tetsuo KITABAYASHI, Journal of the Ceramic Society of Japan 100[1]1-6 (1992)) and Japanese Unexamined Patent Application Publication No. 2003-188247 describe that, when titania (TiO₂) ceramic is introduced into alumina (Al₂O₃) ceramic, and is sintered in a reducing atmosphere, a conductive property is provided, the volume resistance is decreased, and, in addition to the coulomb force, the Johnson-Rahbeck force is exerted, thereby increasing the adsorption force.

In addition, Japanese Patent No. 3370532 and Japanese Unexamined Patent Application Publication No. 2007-254164 report that, similarly, titanium nitride or (Sm, Ce)Al₁₁O₁₈ is added to aluminum nitride.

However, there is no similar report regarding yttrium aluminum oxide ceramics.

Electrostatic chucks made of the above-described metallic oxides have a volume resistance (/Ω·cm) of 1×10¹⁴ or more, and exhibits the characteristics of a coulomb-type electrostatic chuck. Therefore, the adsorption force is proportional to the permittivity and the applied voltage, and is inversely proportional to the thickness. The inventors found that, even when the applied voltage and the thickness are adjusted, it is not possible to obtain a sufficient adsorption force at a permittivity of less than 10 in a frequency range of 1 MHz or less and at a permittivity of less than 30 in a frequency range of 1 kHz or less. However, The inventors found that, when some of yttrium in a yttrium aluminum oxide crystal phase is substituted with a rare earth element (RE) excluding yttrium, the volume resistance is decreased, and a sufficient adsorption force can be obtained even at a permittivity of less than 10 in a frequency range of 1 MHz or less and at a permittivity of less than 30 in a frequency range of 1 kHz or less.

This is because the conductive property is developed by substituting some of yttrium in yttrium aluminum oxide with the rare earth element (RE), and there is an effect that decreases the volume resistance of yttrium aluminum oxide. Therefore, it is considered that, in addition to the Coulomb force originally generated by the dielectric polarization of yttrium aluminum oxide, the Johnson-Rahbeck force affected by electron conduction is supplied, and thus the adsorption force is increased.

In the electrostatic chuck member of the invention, a ratio [N_{RE}/(N_{Y}+N_{RE})] of the number of atoms of the rare earth element excluding yttrium (N_{RE}) to the sum (N_{Y}+N_{RE}) of the number of yttrium atoms (N_{Y}) and the number of the atoms of the rare earth element excluding yttrium (N_{RE}) is in a range of 0.01 to less than 0.5.

At a ratio of less than 0.01, no sufficient effect of the corrosion resistance is observed. In addition, at a ratio of 0.5 or more, the grains of REAlO₃ abnormally grow, and therefore the mechanical strength is decreased. The above-described ratio [N_{RE}/(N_{Y}+N_{RE})] is preferably in a range of 0.05 to less than 0.5, and more preferably in a range of 0.1 to 0.4.

In addition, in the electrostatic chuck member of the invention, the volume resistance of the complex oxide sintered body is required to be in a range of 1×10¹⁰ Ω·cm to less than 1×10¹⁵ Ω·cm. At a volume resistance of less than 1×10¹⁰ Ω·cm, a silicon wafer and a ceramic dielectric body are damaged due to the leak current. In addition, when the volume resistance exceeds 1×10¹⁵ Ω·cm, the Johnson-Rahbeck force does not work, and therefore a sufficient adsorption force cannot be obtained. The volume resistance is preferably in a range of 1×10¹¹ Ω·cm to less than 1×10¹⁴ Ω·cm.

The average particle diameter of the complex oxide sintered body is preferably in a range of 0.5 μm to 30 μm, and more preferably in a range of 0.5 μm to 10 μm.

When the average particle diameter is 0.5 μm or more, it becomes easy to obtain a sufficient volume resistance, and a sufficient adsorption force can be exhibited. In addition, when the average particle diameter is 30 μm or less, it is possible to suppress a decrease in the density and a decrease in the mechanical strength, and to prevent the electrostatic chuck member from being damaged due to dropout or discharge in corrosive gas or plasma thereof.

The dielectric loss (Tan™) of the complex oxide sintered body is preferably in a range of 0.01 to less than 1 at 40 Hz, in a range of 0.001 to less than 0.1 at 1 kHz, and 0.001 or less at 1 MHz. When the dielectric loss is controlled to be within the above-described range, it is possible to obtain a sufficient adsorption force in spite of a low relative permittivity.

Meanwhile, there is a case in which an appropriate volume resistance cannot be obtained when the dielectric loss of the sintered body is less than 0.01 and 1 or more at 40 Hz, and less than 0.001 and 0.1 or more at 1 kHz. In addition, there is a case in which heat is generated in a plasma etching step, and the variation in the adsorption force or damage may be caused due to the temperature increase when the dielectric loss of the sintered compact is more than 0.001 at 1 MHz.

The rare earth element (RE) is preferably selected from samarium (Sm) and gadolinium (Gd) in consideration of an effect that improves the corrosion resistance. In this case, the complex oxide sintered body may contain Sm and Gd at the same time. When the above-described rare earth elements are contained, sufficient corrosion resistance can be obtained.

The crystal structure of the complex oxide obtained by substituting some of yttrium in yttrium aluminum oxide with a rare earth element (RE) excluding yttrium is not particularly limited, but is preferably a garnet-type single phase since the mechanical strength is excellent. However, the structure of the complex oxide may be a perovskite-type crystal phase or a monoclinic crystal phase, or may have the both of the two crystal structures. When the complex oxide has the above-described crystal structure, a mechanical strength with no practical problem can be obtained.

In the above-described complex oxide sintered body, the lattice constant of the garnet-type crystal phase being contained is preferably in a range of more than 1.2005 nm to 1.2060 nm, and furthermore, more preferably in a range of 1.2010 nm to 1.2050 nm.

The lattice constant is considered to be increased by substituting some of yttrium in yttrium aluminum oxide with samarium (Sm) ions (ion radius: 0.109 nm) or gadolinium (Gd) ions (ion radius: 0.107 nm) which is larger than yttrium (Y) ions (ion radius: 0.104 nm), and the increase in the lattice constant serves as an index indicating the substitution proportion.

At a lattice constant of 1.2005 nm or less, the substitution amount of samarium and gadolinium into yttrium aluminum oxide is small, and therefore an appropriate volume resistance cannot be obtained. In addition, when the lattice constant exceeds 1.2060 nm, the upper limit substitution amount is reached, REAlO₃ (RE=Sm or Gd) orthorhombic particles are generated as a byproduct, and the interfusion of a material having a different thermal expansion coefficient causes the degradation of the bending strength.

The electrostatic chuck member of the embodiment can be manufactured, for example, in the following manner.

First, commercially available aluminum oxide (Al₂O₃) powder, commercially available yttrium oxide (Y₂O₃) powder, commercially available samarium oxide (Sm₂O₃) powder, and commercially available gadolinium oxide (Gd₂O₃) powder, all of which are raw material powders and have an average particle diameter of the primary particles in a range of 0.01 μm to 1.0 μm, are used, and are mixed at a predetermined ratio respectively.

Here, when the average particle diameters of the raw material powders are less than 0.01 μm, the prices of the raw material are expensive, and there is a case in which a commercial problem may be caused. In addition, when the average particle diameters become larger than 1.0 μm, the sinterability of the mixture of the raw materials is poor, there is a case in which the density of the sintered body may be decreased, and there is a case in which deterioration of the sintered body in corrosive gas or plasma thereof may be accelerated due to an increase in the particle diameter in the sintered body.

The raw material powders are preferably mixed using a solvent. The solvent is not particularly limited, and, for example, water, alcohols, or the like may be used as the solvent. In addition, a dispersant may be used during the mixing of the raw material powders. The dispersant is not particularly limited, and a dispersant which is adsorbed onto the particle surfaces and increases the dispersion efficiency is used as the dispersant. Furthermore, it is desirable for the dispersant to contain no metallic ion as a counter ion to reduce metallic impurities. The dispersant is also added to prevent the hetero-agglomeration between different particles.

Furthermore, it is efficient to use a disperser for the mixing of the raw material powders. The use of a disperser efficiently adsorbs the dispersant onto the particle surfaces, and enables the uniform mixing of different particles. The disperser is not particularly limited, and, for example, a disperser using media such as an ultrasonic wave, a planetary ball mill, a ball mill, and a sand mill, or a medium-free disperser such as an ultrahigh pressure crushing disperser may be used. Particularly, in a case in which a disperser using a ball mill is employed, alumina balls having a diameter in a range of 1 mm to 5 mm are preferably used since a desired volume resistance is easily obtained. As the diameter of the alumina balls decreases, the mixing and dispersion efficiency of fine particles becomes more favorable, and the volume resistance becomes easily decreased. In addition, the medium-free disperser decreases the interfusion of contaminants, and is particularly advantageous for corrosion-resistant members for a semiconductor manufacturing apparatus.

Next, the raw material powders are granulated using a well-known method, thereby producing granules. The granules are molded into a predetermined shape using well-known molding means. After that, the molded granules are defatted in the atmosphere at a temperature in a range of 50° C. to 600° C., and then are fired in the atmosphere or an inert atmosphere at a temperature in a range of 1400° C. to 1800° C., and preferably in a range of 1550° C. to 1750° C. for one hour to ten hours, whereby a dense sintered body having a sintered density of 98% or more can be produced. When a temperature of firing the molded granules is 1400° C. or lower, the granules are not sintered, and the density does not increase. In addition, when a temperature of firing the molded granules is 1800° C. or higher, the granules are melted, which is not preferable.

Pressureless sintering may be carried out as the firing method, but a pressurization-and-firing method such as hot pressing or hot isostatic pressing (HIP) is preferred for densification. The pressurization force during the pressurization and firing is not particularly limited, but the pressurization force is generally in a range of approximately 10 MPa to 40 MPa.

### EXAMPLES

Hereinafter, the invention will be described in more detail using examples and comparative examples.

### Examples 1 to 15

### The Production of Raw Material Slurry and Granules

Commercially available aluminum oxide (Al₂O₃) powder, commercially available yttrium oxide (Y₂O₃) powder, commercially available samarium oxide (Sm₂O₃) powder, and commercially available gadolinium oxide (Gd₂O₃) powder, all of which had an average particle diameter of the primary particles, which was measured using a transmission electron microscope, of 0.1 mm, were weighed so as to obtain compositions described in Table 1-1. The powder mixtures were adjusted, were wet-mixed using water as a solvent and a ball mill in which alumina balls having a diameter in a range of 1 mm to 5 mm were used, and were granulated using spray drying, thereby producing granule mixtures.

(Production of Molded Bodies and Sintered Bodies)

Next, the powder mixtures were molded into predetermined shapes using well-known molding means (uniaxial pressurization molding (die molding)), thereby producing molded bodies. Next, the molded bodies were pressurized and fired through hot pressing in an argon gas at 1600° C. for two hours, thereby producing sintered bodies. At this time, the pressurization force was 20 MPa.

### Comparative Examples 1 to 7

Sintered bodies were produced so as to obtain compositions described in Table 1-1 using the same method as in Examples 1 to 15.

Next, the sintered bodies of the above-described examples and comparative examples were evaluated. The evaluation results are described in Table 1-2. Meanwhile, the evaluation items and the evaluation methods are as described below.

(1) The Primary Average Particle Diameters of Metal Oxide Powder Raw Materials

The primary average particle diameters were measured using a transmission electron microscope [model number “H-800” manufactured by Hitachi, Ltd.].

(2) The Measurement of the Relative Density

The densities of the sintered bodies were measured using an Archimedes method, and the ratios (relative densities) to the theoretical densities obtained using the following formula were computed.

<Theoretical Density>

Theoretical density=unit cell weight (g)/unit cell volume (cm³)

Unit cell weight: (the unit cell weight of an individual yttrium aluminum oxide crystal phase×the mol % of the individual crystal phase)+(the unit cell weight of an individual REAlO₃ crystal phase×the mol % of the individual crystal phase)

Unit cell volume: (the unit cell volume of the individual yttrium aluminum oxide crystal phase×the mol % of the individual crystal phase)+(the unit cell volume of an individual REAlO₃ crystal phase×the mol % of the individual crystal phase)

The mol % s of the individual crystal phases of yttrium aluminum oxide and REAlO₃ were computed from the estimation of the preparation amounts and X-ray diffraction peak intensities of the raw material powders.

(3) The Average Particle Diameters of the Complex Oxide Sintered Bodies

The surfaces of the sintered bodies were mirror-polished, then, were thermally etched at 1300° C. for 30 minutes, and the average particle diameters were measured from SEM images of arbitrary five points using a scanning electron microscope [model number “S-4000” manufactured by Hitachi, Ltd.].

Meanwhile, in each point on the SEM images of arbitrary five points, particles in a 100 μm×70 μm rectangular range were measured at a scale of 1000 times.

(4) The Identification of the Crystal Phases in the Sintered Bodies

Crystal phases were identified using a powder X-ray diffraction method and, as an X-ray diffraction apparatus, a model number “X′ Pert PRO MPD” manufactured by PANalytial B.V. In Table 1-1, G and M represent the garnet-type crystal phase and monoclinic crystal phase of yttrium aluminum oxide respectively. In addition, O represents the orthorhombic crystal phase of REAlO₃.

(5) The Measurement of the Lattice Constant

The lattice constants were measured using a powder X-ray diffraction method and the above-described X-ray diffraction apparatus. The sintered bodies were crushed into a powder form, and six or more peaks having a 2θ at near 90°, which were identified as the garnet-type crystal phase, were used, thereby computing the lattice constants using an internal reference method.

(6) The Relative Permittivity and Dielectric Loss of the Sintered Bodies

The permittivity and dielectric losses at frequencies of 40 Hz, 1 kHz, and 1 MHz were measured using a model number “Agilent 4294A Precision Impedance Analyzer” manufactured by Agilent Technologies as a measurement device. The sintered bodies were processed into 60 mm×60 mm×2 mm, and were used.

(7) Intrinsic Volume Resistance

The intrinsic volume resistance was measured using a three-terminal method. The intrinsic volume resistance was obtained through the conversion from the current value at an applied voltage of 500 V and a retention time of 60 seconds using a model number “Digital Ultrahigh Resistance/Micro Current Meter R83040A” manufactured by Advantest Corporation as a measurement device. The sintered bodies were processed into 60 mm×60 mm×1 mm, and were used.

(8) The Adsorption Forces of the Sintered Bodies

The sintered bodies were processed to have a thickness of 0.5 mm, were adhered in a configuration of aluminum ceramic/electrode/sintered body, and the adsorption forces to a 2 inch-silicon wafer were measured under conditions of applied voltages of 0.5 kV, 1.0 kV, 1.5 kV, 2.0 kV, and 2.5 kV, and an application time of 60 seconds in a vacuum (<0.5 Pa). The measurement was carried out through peeling using a load cell, and the maximum peeling stress generated at this time was considered as the adsorption force.

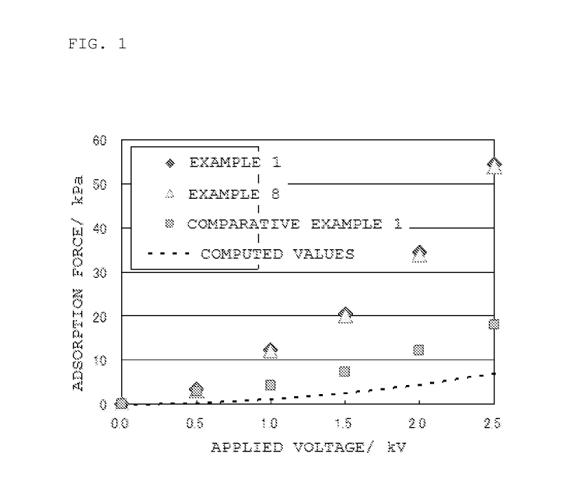

Meanwhile, FIG. 1 illustrates the measurement results of the adsorption forces of the sintered bodies of Examples 1 and 8 and Comparative Example 1 at the above-described applied voltages. The dotted line in FIG. 1 indicates the results of the adsorption forces of a coulomb force-type electrostatic chuck at the respective applied voltages obtained from the formula (1) described below. The longer distances of the measurement results of the respective examples from the dotted line indicate the increases in the adsorption forces due to the exertion of the Johnson-Rahbeck force in addition to the Coulomb force.

In addition, Table 1-2 describes the measurement results of the adsorption forces of the sintered bodies of the respective examples and comparative examples at 1.5 kV.

(9) The Four-Point Bending Strengths of the Sintered Bodies

Test specimens in accordance with JISR1601 were cut out from the samples, and the bending strengths (average strengths of ten points) were measured using a model number “INSTRON 4206-type Universal Testing Machine” manufactured by INSTRON in four-point bending tests.

(10) The Consumption Rates (Etching Rates) of the Sintered Bodies

10 mm×10 mm×5 mm sheet-like bodies were cut out from the samples, and the bodies were mirror-polished on one surface, thereby producing test specimens having a polished surface that was used as a test surface. Next, the test specimens were washed using acetone, then, the weights of the test specimens were measured, and the test specimens were installed in the chamber of a plasma etching apparatus. Next, CF₄ gas and micro waves (100 W) were introduced into the chamber so as to generate CF₄ plasma, and the respective test specimens were exposed to the CF₄ plasma. After that, the weights of the test specimens after the exposure were measured, the consumption rates (etching rates) were computed from the weight changes before and after the exposure, and the corrosion resistance was evaluated.

Meanwhile, the exposure conditions are an atmosphere pressure of 11 torr, an exposure time of ten minutes, and an exposure temperature of 900° C.

TABLE 1

| | | | | | | Average | | |
|---|---|---|---|---|---|---|---|---|
| | | Al₂O₃—Y₂O₃—RE₂O₃ | | Sintering | Relative | particle | | Lattice |
| | | composition | Atom ratio | temperature | density | diameter | Crystal | constant |
| | No. | (RE = Sm or Gd) | N_{RE}/(N_{Y} + N_{RE} ) | (° C.) | (%) | (μm) | phase | (nm) |
| Examples | 1 | 5.0Al₂O₃•2.7Y₂O₃•0.3Sm₂O₃ | 0.1 | 1500 | 99.9 | 1.1 | G | 1.2022 |
| | 2 | 5.0Al₂O₃•2.7Y₂O₃•0.3Sm₂O₃ | 0.1 | 1600 | 99.5 | 6.8 | G | 1.2023 |
| | 3 | 5.0Al₂O₃•2.7Y₂O₃•0.3Sm₂O₃ | 0.1 | 1700 | 98.5 | 23 | G | 1.2023 |
| | 4 | 5.0Al₂O₃•4.5Y₂O₃•0.5Sm₂O₃ | 0.1 | 1600 | 99.8 | 4.8 | G, M | 1.2023 |
| | 5 | 5.0Al₂O₃•2.4Y₂O₃•0.6Sm₂O₃ | 0.2 | 1600 | 99.4 | 10.1 | G | 1.2039 |
| | 6 | 5.0Al₂O₃•2.1Y₂O₃•0.9Sm₂O₃ | 0.3 | 1600 | 99.1 | 14.8 | G | 1.2045 |
| | 7 | 5.0Al₂O₃•1.8Y₂O₃•1.2Sm₂O₃ | 0.4 | 1600 | 99.0 | 19.8 | G | 1.2054 |
| | 8 | 5.0Al₂O₃•2.7Y₂O₃•0.3Gd₂O₃ | 0.1 | 1500 | 99.8 | 1.1 | G | 1.2016 |
| | 9 | 5.0Al₂O₃•2.7Y₂O₃•0.3Gd₂O₃ | 0.1 | 1600 | 99.9 | 5.8 | G | 1.2017 |
| | 10 | 5.0Al₂O₃•2.7Y₂O₃•0.3Gd₂O₃ | 0.1 | 1700 | 98.1 | 27 | G | 1.2017 |
| | 11 | 5.0Al₂O₃•4.5Y₂O₃•0.5Gd₂O₃ | 0.1 | 1600 | 99.7 | 5.5 | G, M | 1.2017 |
| | 12 | 5.0Al₂O₃•2.4Y₂O₃•0.6Gd₂O₃ | 0.2 | 1600 | 99.8 | 9.8 | G | 1.2025 |
| | 13 | 5.0Al₂O₃•2.1Y₂O₃•0.9Gd₂O₃ | 0.3 | 1600 | 99.1 | 14.5 | G | 1.2032 |
| | 14 | 5.0Al₂O₃•1.8Y₂O₃•1.2Gd₂O₃ | 0.4 | 1600 | 99.2 | 20.1 | G | 1.2045 |
| | 15 | 5.0Al₂O₃•2.7Y₂O₃•0.15Sm₂O₃•015 | 0.1 | 1600 | 99.8 | 6.0 | G | 1.2020 |
| | | Gd₂O₃ | | | | | | |
| Comparative | 1 | 5.0Al₂O₃•3.0Y₂O₃ | 0.0 | 1600 | 99.8 | 2.1 | G | 1.2005 |
| Examples | 2 | 5.0Al₂O₃•1.5Y₂O₃•1.5Sm₂O₃ | 0.5 | 1600 | 99.2 | 18.8 | G, O | 1.2068 |
| | 3 | 5.0Al₂O₃•1.5Y₂O₃•1.5Gd₂O₃ | 0.5 | 1600 | 99.1 | 17.5 | G, O | 1.2061 |
| | 4 | 5.0Al₂O₃•2.7Y₂O₃•0.3Sm₂O₃ | 0.1 | 1400 | 99.0 | 0.45 | G | 1.2005 |
| | 5 | 5.0Al₂O₃•2.7Y₂O₃•0.3Sm₂O₃ | 0.1 | 1800 | 97.5 | 38 | G | 1.2025 |
| | 6 | 5.0Al₂O₃•2.7Y₂O₃•0.3Gd₂O₃ | 0.1 | 1400 | 98.9 | 0.48 | G | 1.2005 |
| | 7 | 5.0Al₂O₃•2.7Y₂O₃•0.3Gd₂O₃ | 0.1 | 1800 | 97.6 | 35 | G | 1.2020 |

TABLE 2

| | | | | | | | | | Adsorption | | |
|---|---|---|---|---|---|---|---|---|---|---|---|
| | | | | | | | | Volume | force | Bending | Consumption |
| | | Permittivity | | | Dielectric loss | | | resistance | @ 1.5 kV | strength | rate |
| | No. | 40 Hz | 1 kHz | 1 MHz | 40 Hz | 1 kHz | 1 MHz | Ω · cm | (kPa) | (MPa) | (μm/minute) |
| Examples | 1 | 8.0 | 7.8 | 7.8 | 0.0573 | 0.0030 | 0.0003 | 1.4E+14 | 20 | 200 | 0.001 |
| | 2 | 8.7 | 7.6 | 7.6 | 0.2787 | 0.0196 | 0.0003 | 5.7E+12 | 30 | 170 | 0.001 |
| | 3 | 8.5 | 7.5 | 7.5 | 0.8756 | 0.0803 | 0.0008 | 1.4E+10 | 40 | 150 | 0.050 |
| | 4 | 9.0 | 8.0 | 8.0 | 0.3210 | 0.0329 | 0.0003 | 5.0E+12 | 35 | 178 | 0.002 |
| | 5 | 10.8 | 7.9 | 7.7 | 0.5701 | 0.0509 | 0.0006 | 1.3E+13 | 20 | 160 | 0.005 |
| | 6 | 11.0 | 8.5 | 8.5 | 0.6853 | 0.0603 | 0.0006 | 5.0E+11 | 30 | 152 | 0.012 |
| | 7 | 12.0 | 10.0 | 9.0 | 0.7583 | 0.0798 | 0.0007 | 5.0E+10 | 40 | 160 | 0.020 |
| | 8 | 8.0 | 7.8 | 7.8 | 0.0583 | 0.0032 | 0.0003 | 1.2E+14 | 20 | 210 | 0.001 |
| | 9 | 8.7 | 7.6 | 7.6 | 0.2830 | 0.0206 | 0.0003 | 5.0E+12 | 30 | 180 | 0.001 |
| | 10 | 9.0 | 8.0 | 7.8 | 0.8536 | 0.0853 | 0.0008 | 1.2E+10 | 38 | 150 | 0.048 |
| | 11 | 9.0 | 8.0 | 8.0 | 0.3222 | 0.0341 | 0.0003 | 5.0E+12 | 35 | 180 | 0.002 |
| | 12 | 10.5 | 7.5 | 7.5 | 0.5613 | 0.0523 | 0.0006 | 1.5E+13 | 20 | 158 | 0.005 |
| | 13 | 10.5 | 8.5 | 8.4 | 0.6535 | 0.0613 | 0.0006 | 5.0E+11 | 30 | 150 | 0.013 |
| | 14 | 11.5 | 9.8 | 9.5 | 0.7683 | 0.0786 | 0.0007 | 5.0E+10 | 40 | 158 | 0.022 |
| | 15 | 8.7 | 7.6 | 7.6 | 0.2683 | 0.0232 | 0.0003 | 5.7E+12 | 30 | 170 | 0.002 |
| Comparative | 1 | 17.8 | 10.0 | 8.8 | 0.0009 | 0.0004 | 0.0006 | 2.0E+15 | 7 | 160 | 0.135 |
| Examples | 2 | 11.0 | 9.0 | 9.0 | 0.8653 | 0.0812 | 0.0008 | 7.0E+11 | 25 | 112 | 0.056 |
| | 3 | 11.0 | 9.0 | 9.0 | 0.8375 | 0.0801 | 0.0008 | 8.0E+11 | 28 | 103 | 0.063 |
| | 4 | 8.0 | 7.5 | 7.5 | 0.0086 | 0.0008 | 0.0001 | 2.0E+15 | 5 | 200 | 0.005 |
| | 5 | 9.0 | 8.0 | 8.0 | 1.1325 | 0.1256 | 0.0018 | 1.0E+09 | 50 | 100 | 0.132 |
| | 6 | 8.0 | 7.5 | 7.5 | 0.0079 | 0.0007 | 0.0001 | 2.0E+15 | 5 | 200 | 0.006 |
| | 7 | 9.0 | 8.0 | 8.0 | 1.1536 | 0.1348 | 0.0020 | 1.1E+09 | 50 | 100 | 0.125 |

The following facts were clarified from the above-described evaluation results.

In the compositions in which samarium oxide (Sm₂O₃) was introduced into yttrium aluminum oxide as in Examples 1 to 3, the relative densities were 98% or more, the sintered bodies were dense, and garnet-type crystal structures were formed. In addition, the lattice constants were approximately 1.202 nm. There were tendencies that, as the sintering temperature increased, the average particle diameters became greater, the dielectric losses at frequencies of 40 Hz and 1 kHz increased, the volume resistances decreased, and the adsorption forces increased. The sintered bodies had a low relative permittivity in a range of 7.5 to 8, but the adsorption forces reached large values of 20 kPa or more at applied voltages of 1.5 kV or more. The adsorption force of the coulomb force-type electrostatic chuck is expressed by the following formula. Since the computed value at an applied voltage of 1.5 kV is approximately 2.5 kPa, the value increases approximately eight times (refer to FIG. 1).

F=½∈₀∈ᵣ²(V/d)² Formula (1)

In the above-described formula (1), ∈₀ represents the permittivity in a vacuum, ∈ᵣ represents the permittivity of a dielectric body, V represents the applied voltage (V), and d represents the thickness (m) of the dielectric body.

The above-described results show that the electric conductivity is developed by introducing samarium oxide into yttrium aluminum oxide. In addition, it is considered that, as the volume resistance decreases, a fine current flows in a gap between the silicon wafer and the surface of the sintered body so as to cause dielectric polarization, and the Johnson-Rahbeck force is exerted together with the Coulomb force, and therefore the adsorption force increases. In addition, the bending strength and the consumption rate were practically sufficient values.

In Example 4, the yttrium aluminum oxide crystal structure was set to the garnet-type and monoclinic-type mixed crystal body by changing the composition of Al₂O₃—Y₂O₃—Sm₂O₃, but almost the same results as in Examples 1 to 3 were obtained.

In addition, when the atom ratio (N_{RE}/N_{Y}+N_{RE}) was increased to a value in a range of 0.2 to 0.4 as in Examples 5 to 7, there were tendencies that the average particle diameter and the lattice constant became great, the dielectric losses at frequencies of 40 Hz and 1 kHz increased, the volume resistance decreased, and the adsorption force increased. Here, in N_{RE}/N_{Y}+N_{RE}, the ratio of the rare earth element represents the ratio of the number of atoms of either or both of samarium and gadolinium (N_{RE}) to the sum (N_{Y}+N_{RE}) of the number of yttrium atoms (N_{Y}) and the number of the atoms of either or both of samarium and gadolinium (N_{RE}).

While Examples 8 to 14 were carried out with samarium oxide in the compositions of Examples 1 to 7 changed to gadolinium oxide, the same effects as a case in which samarium oxide was introduced were obtained.

Example 15 is a system in which samarium oxide and gadolinium oxide were introduced as the rare earth oxide at the same time into yttrium aluminum oxide. In this system as well, the same effects as in Example 2 or 9 were obtained, and practically sufficient bending strength and consumption rate were obtained together with a great adsorption force.

Comparative Example 1 was an yttrium aluminum oxide single body, but it was found that, when the rare earth element was not introduced, the dielectric losses at frequencies of 40 Hz and 1 kHz were smaller than 0.01 and 0.001 respectively, and the lattice constant also exhibited a small value of 1.2005 nm. In addition, the volume resistance was 1×10¹⁵ Ω·cm or more, and the adsorption force at an applied voltage of 1.5 kV was as small as 7 kPa. Furthermore, the consumption rate was also 0.1 μm/minute or more, and the corrosion resistance was poor.

Comparative Examples 2 and 3 were systems in which the atom ratios (N_{RE}/N_{Y}+N_{RE}) were increased to 0.5, thereby increasing the amounts of the rare earth oxide being introduced, which caused the lattice constants to exhibit great values of 1.2060 nm or more, REAlO₃ (RE=Sm or Gd) which is an orthorhombic crystal phase to be generated as a byproduct, and the bending strengths to be decreased by the interfusion of a material having a different thermal expansion coefficient.

In a case in which the sintering temperature was low as in Comparative Examples 4 and 6, the average particle diameter was smaller than 0.5 am, the dielectric losses at frequencies of 40 Hz and 1 kHz were smaller than 0.01 and 0.001 respectively, the volume resistance was 1×10¹⁵ Ω·cm or more, and the adsorption force at an applied voltage of 1.5 kV was as small as 5 kPa. The reason for the high volume resistance was, in a case in which the sintering temperature was low, the difficulty of the rare earth element (RE) to be substituted into yttrium sites in yttrium aluminum oxide, and the lattice constant exhibited a small value of 1.2005 nm. Furthermore, the reason is considered to be the presence of a highly insulating unreacted layer. Conversely, in a case in which the sintering temperature was set to a high temperature as in Comparative Examples 5 and 7, the adsorption force was sufficient, but the bending strength or consumption rate was poor. In addition, the volume resistance was 1×10¹⁰ Ω·cm or less, and the dielectric loss at 1 MHz was 0.001 or more, and therefore there is a concern that a silicon wafer or a ceramic dielectric body layer may be damaged in a plasma etching process.

As described above, according to the electrostatic chuck member of the invention, a portion exposed to corrosive gas or plasma thereof is made of a complex oxide sintered body obtained by substituting some of yttrium in yttrium aluminum oxide with a rare earth element (RE) excluding yttrium, and in the sintered body, some of yttrium in yttrium aluminum oxide is substituted with the rare earth element (RE) excluding yttrium, it is possible to provide an electrostatic chuck for manufacturing a semiconductor with a commercially sufficient adsorption force of 10 kPa or more at an applied voltage of 1.5 kV without causing deterioration or the generation of particles even when being exposed to the above-described corrosive gas or plasma by controlling the amount of the rare earth oxide being added, the dielectric loss and volume resistance of the sintered body.

In addition, since the thickness of the dielectric layer can be increased compared with the metal oxide of the related art in accordance with the increased adsorption force, the voltage resistance is also improved, and the risk of damage during an operation is reduced. In addition, the risk of cracking during a process is also reduced.

1. An electrostatic chuck member, which is made of a complex oxide sintered body obtained by substituting some of yttrium in yttrium aluminum oxide with a rare earth element (RE) excluding yttrium,
wherein a ratio [N_{RE}/(N_{Y}+N_{RE})] of the number of atoms of the rare earth element excluding yttrium (N_{RE}) to the sum (N_{Y}+N_{RE}) of the number of yttrium atoms (N_{Y}) and the number of the atoms of the rare earth element excluding yttrium (N_{RE}) is in a range of 0.01 to less than 0.5, and
a volume resistance of the complex oxide sintered body is in a range of 1×10¹⁰ Ω·cm to less than 1×10¹⁵ Ω·cm.

2. The electrostatic chuck member according to claim 1,
wherein an average particle diameter of the complex oxide sintered body is in a range of 0.5 μm to 30 μm.

3. The electrostatic chuck member according to claim 1,
wherein a dielectric loss (tan δ) of the complex oxide sintered body is in a range of 0.01 to less than 1 at 40 Hz, is in a range of 0.001 to less than 0.1 at 1 kHz, and is 0.001 or less at 1 MHz.

4. The electrostatic chuck member according to claim 1,
wherein the rare earth element (RE) excluding yttrium is samarium and/or gadolinium.

5. The electrostatic chuck member according to claim 1,
wherein, in the complex oxide sintered body, a lattice constant of a garnet-type crystal phase being contained is in a range of greater than 1.2005 nm to 1.2060 nm.
